(19) United States
(12) Patent Application Publication
(10) Pub. No.: US 2006/0260749 A1
(43) Pub. Date: Nov. 23, 2006

(54) Substrate processing apparatus and substrate processing method

(76) Inventors: Satoshi Ueda, Toyama (JP); Tamaki Nakajima, Toyama (JP)

Correspondence Address: MCDERMOTT WILL & EMERY LLP, 600 13TH STREET, N.W., WASHINGTON, DC, 20005-3096, US

(21) Appl. No.: 11/378,383

(22) Filed: Mar. 20, 2006

(30) Foreign Application Priority Data
May 20, 2005 (JP) 2005-148715

(51) Int. Cl. C23F 1/00; C23C 16/00

(52) U.S. Cl. 156/345.34; 118/715

(57) ABSTRACT

A substrate processing apparatus comprises: a reaction chamber for processing a substrate using a process gas; a pedestal provided in the reaction chamber and placing the substrate; and a shower head for introducing the process gas into the reaction chamber. The shower head includes a gas dispersion plate which is formed with a plurality of penetrating holes for diffusing the process gas and is provided to face the pedestal. The gas dispersion plate includes a central portion and a perimeter portion having a smaller thickness than the central portion, and the ones of the plurality of penetrating holes provided in the perimeter portion have a smaller length than the ones of the plurality of penetrating holes provided in the central portion.

### CROSS-REFERENCE TO RELATED APPLICATIONS

This application claims priority under 35 U.S.C. §119 on Patent Application No. 2005-148715 filed in Japan on May 20, 2005, the entire contents of which are hereby incorporated by reference.

### BACKGROUND OF THE INVENTION

(a) Fields of the Invention

The present invention relates to substrate processing apparatuses and substrate processing methods. In particular, the present invention relates to substrate processing apparatuses and substrate processing methods capable of improving the uniformity of processing such as film formation or etching.

(b) Description of Related Art

In recent years, there has been a growing trend in semiconductor integrated circuit devices toward a larger packing density and a lower power consumption, while manufacturing costs of the devices have increasingly dropped due to enlargement of diameter of a semiconductor substrate or other approaches. In order to simultaneously attain miniaturization of pattern size of elements in the semiconductor integrated circuit device and enlargement of the substrate, a manufacturing process of the device requires a reduced variation in the thickness of an insulating film which is a component of the semiconductor integrated circuit device, a uniform dry etching over the entire surface of the substrate, and the like.

FIG. 5A is a sectional view showing an example of substrate processing apparatuses, more specifically, an example of conventional chemical vapor deposition (CVD) apparatuses for forming a thin film such as a silicon oxide film or a polysilicon film on a semiconductor substrate. With enlargement of diameter of a semiconductor substrate used for device manufacturing, a single wafer type apparatus as shown in FIG. 5A becomes mainstream. Note that a thermal CVD apparatus is shown in this figure.

A conventional chemical vapor deposition apparatus 10 shown in FIG. 5A has a pedestal 12 provided in a reaction chamber 11, and a substrate 13 is placed on the pedestal 12. In an upper portion of the reaction chamber 11, a shower head 14 is provided to face the pedestal 12. An upper portion of the shower head 14 is provided with a gas inlet 15, and a source gas 16 is introduced through the gas inlet 15 into the shower head 14. The side of the shower head 14 facing the substrate 13 (the downside thereof when viewed in the chemical vapor deposition apparatus 10 of FIG. 5) is provided with a gas dispersion plate 17, and the shower head 14 and the gas dispersion plate 17 form a hollow space 18. The reaction chamber 11 is provided with an exhaust vent 19, and the apparatus is designed so that a pump (not shown) can exhaust gas from the inside of the reaction chamber 11. The pedestal 12 is provided with a heater (not shown) for adjusting the temperature of the substrate 13.

FIG. 5B is a longitudinal sectional view showing in enlarged dimension part of the gas dispersion plate 17 in FIG. 5A. Referring to FIG. 5B, the gas dispersion plate 17 is provided with a great number of penetrating holes 20 of small diameters for supplying the source gas 16 into the reaction chamber 11 and blowing it onto the substrate 12.

The shower head 14 and the gas dispersion plate 17 may be formed integrally. However, the integrally-formed structure makes it difficult to do manufacturing and maintenance, so that the shower head 14 and the gas dispersion plate 17 are typically formed as separable independent components.

In the case where a thin film is formed using the conventional chemical vapor deposition apparatus 10 having the structure shown above, first, the substrate 13 is placed on the pedestal 12 in the reaction chamber 11, and heated with a heater to a predetermined temperature.

Next, with gas within the reaction chamber 11 exhausted from the exhaust vent 19, the source gas 16 necessary for film formation is introduced through the gas inlet 15 into the shower head 14. The source gas 16 introduced from the shower head 14 passes through the penetrating holes 20 formed in the gas dispersion plate 17, and is supplied to the reaction chamber 11. Then, the supplied gas is blown onto the substrate 13 to form a thin film on the substrate 13.

The gas dispersion plate 17 will be further described in detail. The gas dispersion plate 17 has a great number of fine penetrating holes 20 with a diameter of, for example, about 0.5 mm formed over the almost entire region of the circular plate. As shown in FIG. 5B, each of the penetrating holes 20 has a uniform shape extending from the gas inlet to the vent.

In the film formation, the source gas 16 is introduced in the order in which the gas passes through the gas inlet 15 and is blown onto the center portion of the shower head 14. By the gas dispersion plate 17, the introduced source gas 16 is horizontally dispersed in the hollow space 18 and then discharged through the penetrating holes 20 into the reaction chamber 11. As a result of this, the discharged source gas 16 is uniformly supplied onto the substrate 13, so that the thin film deposited on the substrate 13 can have a uniform thickness.

The chemical vapor deposition apparatus employing the gas dispersion plate 17 as shown above is described in, for example, Japanese Unexamined Patent Publication No. 2000-273638 (referred hereinafter to as Document 1). As to a dry etching apparatus, the structure of an etching gas dispersion plate with an improved etching uniformty is described in Japanese Unexamined Patent Publication No. H06-204181 (referred hereinafter to as Document 2).

### SUMMARY OF THE INVENTION

The conventional chemical vapor deposition apparatus 10 and the thin film formation method shown in FIGS. 5A and 5B, however, have the following problems.

Associated with miniaturization of semiconductor integrated circuit devices, a more precise process control has come to be demanded. This makes it difficult to deposit a film with a sufficient thickness uniformity for the purpose of fabricating the semiconductor integrated circuit device with a high yield. To be more specific, for example, the thin film formed on the substrate 13 has a thickness smaller in the vicinity of the peripheral portion than in the vicinity of the center. This would result from the following fact.

In the film formation using the chemical vapor deposition apparatus shown in FIG. 5A, ideally, the pressure of the source gas 16 is uniform and thereby the source gas 16 is supplied at an equal flow rate from the penetrating holes 20 in both of the center and edge portions of the shower head 14. To accomplish this, a great number of penetrating holes 20 are formed over the entire surface of the gas dispersion plate 17 with an almost uniform density.

However, in reality, since the source gas 16 is introduced from the gas inlet 15 which is provided to face the vicinity of the center of the shower head 14, the pressure of the source gas 16 within the hollow space 18 is lower around the edge portion than around the center portion. Therefore, the penetrating holes 20 around the perimeter of the gas dispersion plate 17 are supplied with the source gas 16 of a smaller flow rate than those around the center portion, and then the supplied gas is discharged from the respective holes into the reaction chamber 11. As a result of this, the flow rate of the source gas 16 blown onto the substrate 13 facing the gas dispersion plate 17 differs depending on the position on the substrate 13. That is to say, the vicinity of the perimeter of the substrate 13 is supplied with the source gas 16 having a smaller flow rate than the vicinity of the center portion thereof.

From the reason mentioned above, it is conceivable that distribution is made in the thickness of the thin film formed on the substrate 13, concretely, the film formed around the perimeter of the substrate 13 becomes thinner than that around the center thereof.

For a dry etching apparatus, an equivalent technique to thus improve the nonuniformity of reaction such as film formation by the single wafer type substrate processing apparatus is described in Document 2. This is the technique in which variation is produced in the diameters of the penetrating holes in order to ensure a uniform density of a reaction gas discharged from the entire surface of an electrode plate corresponding to the gas dispersion plate 17. To be more specific, the penetrating holes in the center of the electrode plate are made to have decreased diameters and those in the perimeter thereof are made to have increased diameters. According to this technique, appropriate setting of the diameter distribution of the penetrating holes can improve the etching uniformity (the value obtained by dividing the difference between the maximum and the minimum by the double of the average) to 3.3%.

The etching uniformity obtained by the technique of Document 2, however, is still inadequate to fabricate a semiconductor integrated circuit with a dimension as fine as 0.25 μm or smaller, and it is conceivable that a further improved uniformity is needed.

In addition, it is considered that if this technique is applied to the gas dispersion plate of the chemical vapor deposition apparatus, the uniformity of the flow rate distribution of the source gas does not reach to a level enough to fabricate a miniaturized semiconductor integrated circuit.

Moreover, if the diameters and the diameter distribution of the penetrating holes are adjusted in order to improve the uniformity of substrate processing by the technique mentioned above, even a minute adjustment may degrade the uniformity of the substrate processing, resulting in a uniformity as poor as 10% or more (see Document 2). Consequently, with the cenventional technique, the uniformity fluctuates responsively to the diameters and the distribution of the penetrating holes, so that it is extremely difficult to obtain a uniformity of 3% or higher on average.

From this result, in order to improve the uniformity of the discharge amount of the source gas 16 by making the diameters of the penetrating holes 20 larger around the perimeter of the gas dispersion plate 17 than around the center portion thereof, the diameters of the penetrating holes 20 should be controlled with an extremely high degree of accuracy. To be more specific, in the case of film deposition by the chemical vapor deposition apparatus, from experiments by the inventors, the penetrating holes 20 have to be formed to have diameters with an accuracy of, for example, 0.01 mm or lower.

The penetrating holes 20 are typically bored with a drill, but the drill capable of ensuring the above-described accuracy of formation required to control those diameters is hard to obtain. Therefore, it is difficult to accomplish the improvement in the uniformity of the film thickness by controlling the diameters of the penetrating holes 20.

In view of the problems mentioned above, the present invention proposes a substrate processing apparatus and a substrate processing method which can carry out substrate processing such as a CVD and a dry etching uniformly over the wafer surface of a substrate.

A first substrate processing apparatus according to the present invention comprises: a reaction chamber for processing a substrate using a process gas; a pedestal for placing the substrate, the member being provided in the reaction chamber; and a shower head for introducing the process gas into the reaction chamber. The shower head includes a gas dispersion plate which is formed with a plurality of penetrating holes for diffusing the process gas and is provided to face the pedestal. The gas dispersion plate includes a central portion and a perimeter portion having a smaller thickness than the central portion, and the ones of the plurality of penetrating holes provided in the perimeter portion have a smaller length than the ones of the plurality of penetrating holes provided in the central portion.

With the first substrate processing apparatus, the gas dispersion plate includes a central portion and a perimeter portion having a smaller thickness than the central portion, and and the penetrating holes provided in the perimeter portion of the gas dispersion plate have a smaller length than the penetrating holes provided in the central portion thereof. From this, resistance occurring when the process gas passes is lower through the penetrating holes provided in the perimeter portion than through the penetrating holes provided in the central portion. That is to say, the process gas passes more easily through the penetrating holes provided in the perimeter portion than the penetrating holes provided in the central portion. This suppresses, in the perimeter portion with a lower process gas pressure than the central portion, a decrease in the amount of the process gas passing through the penetrating hole and discharged into the reaction chamber, whereby the difference in the discharge amount of the process gas depending on the location in the gas dispersion plate can be small. As a result of this, the amount of the process gas supplied onto the substrate is made more uniform over the substrate surface than that of the conventional technique, so that the substrate can be processed more uniform than the conventional technique.

In the present invention, the substrate processing includes, for example, film deposition by a CVD method or the like and dry etching such as plasma etching, but it is not limited to any particular technique.

Preferably, the gas dispersion plate has a thickness decreasing with the distance from the center of the gas dispersion plate, and the plurality of penetrating holes have lengths decreasing with the distance from the center of the gas dispersion plate.

With this apparatus, as the penetrating hole is located more apart from the center of the gas dispersion plate, resistance occurring when the process gas passes through that hole can be further reduced according to the distance (that is, passage of the process gas can be further facilitated). As a result of this, the respective amounts of the process gas discharged from the plurality of penetrating holes provided in the gas dispersion plate can be certainly made uniform, and thereby uniform substrate processing can be carried out reliably.

Preferably, the perimeter portion has a thickness equal to or more than one half of the thickness of the central portion, and the ones of the plurality of penetrating holes provided in the perimeter portion have a length equal to or more than one half of the length of the ones of the plurality of penetrating holes provided in the central portion.

With this apparatus, the respective amounts of the process gas discharged from the plurality of penetrating holes provided in the gas dispersion plate can be certainly made uniform, and thereby uniform substrate processing can be carried out more reliably.

Preferably, the first substrate processing apparatus further comprises a gas inlet which is connected to the shower head so that it faces the central portion of the gas dispersion plate and which is provided to introduce the process gas into the shower head, and the gas dispersion plate is detachable.

With this apparatus, by introducing the process gas into the shower head so that the gas is blown onto the central portion of the gas dispersion plate, the respective amounts of the process gas discharged from the plurality of penetrating holes provided in the gas dispersion plate can be made uniform certainly, and thereby uniform substrare processing can be carried out reliably. Moreover, since it is possible to detach the gas dispersion plate from the shower head, manufacturing and maintenance of the shower head and the gas dispersion plate are facilitated.

Preferably, the plurality of penetrating holes have circular plan shapes. The penetrating hole of a circular plan shape is easy to form, which easily realizes the effects of the present invention that uniform substrate processing is allowed.

Next, a second substrate processing apparatus according to the present invention comprises: a reaction chamber for processing a substrate using a process gas; a pedestal for placing the substrate, the member being provided in the reaction chamber; a first shower head for introducing the process gas into the reaction chamber; and a second shower head formed to surround the first shower head and discharging the process gas into the reaction chamber. The first shower head includes a first gas dispersion plate which is formed with a plurality of first penetrating holes for diffusing the process gas. The second shower head includes a second gas dispersion plate which is formed with a plurality of second penetrating holes for diffusing the process gas and is provided to face the pedestal. At least either of the first and second gas dispersion plates includes a central portion and a perimeter portion having a smaller thickness than the central portion, and the ones of the plurality of first and second penetrating holes provided in the perimeter portion have a smaller length than the ones of the plurality of first and second penetrating holes provided in the central portion.

With the second substrate processing apparatus, in at least either of the first and second gas dispersion plates, the penetrating holes provided in the perimeter portion are shorter than those provided in the central portion. From this, resistance occurring when the process gas passes becomes lower through the penetrating holes provided in the perimeter portion than through the penetrating holes provided in the central portion. Thus, a uniform supply amount of the process gas is supplied onto the substrate, so that uniform substrate processing can be carried out.

First, if the first gas dispersion plate has the structure shown above, the process gas is discharged, from the first penetrating holes provided in the first gas dispersion plate, uniformly over the surface of the first gas dispersion plate. Therefore, inside the second shower head surrounding the first shower head, the pressure of the process gas becomes uniform over the surface of the second gas dispersion plate. As a result of this, the amount of the process gas supplied through the second gas dispersion plate onto the substrate is made uniform over the substrate surface, whereby a more uniform substrate processing can be carried out.

If the second gas dispersion plate has the structure shown above, the process gas is discharged, from the first shower head, nonuniformly over the surface of the first gas dispersion plate as in the case of the conventional substrate processing apparatus. To be more specific, the discharge amount is smaller around the perimeter of the first gas dispersion plate than around the center thereof. However, after this discharge, the second shower head can supplement the uniformity of the discharge amount of the process gas. Specifically, the process gas passes through the plurality of penetrating holes provided in the second gas dispersion plate, and is discharged uniformly over the surface of the second gas dispersion plate. With this mechanism, the process gas is supplied onto the substrate at a uniform supply amount over the substrate surface, so that substrate processing can be reliably carried out uniformly over the substrate surface.

Preferably, the at least either of the gas dispersion plates indicates both of the first and second gas dispersion plates.

With this apparatus, both of the first and second gas dispersion plates have the structure shown above, whereby the amount of the process gas supplied onto the substrate surface can be made uniform in two steps. Thus, the supply amount of the process gas can be made uniform more reliably, and thereby a more uniform substrate processing can be carried out.

As described above, either or both of the first and second gas dispersion plates can have the structure as described previously to carry out uniform substrate processing reliably.

Preferably, the at least either of the gas dispersion plates has a thickness decreasing with the distance from the center of the at least either of the gas dispersion plates, and of the plurality of first and second penetrating holes, the ones formed in the at least either of the gas dispersion plates have lengths decreasing with the distance from the center of the at least either of the gas dispersion plates.

With this apparatus, as the penetrating hole is located more apart from the center of the gas dispersion plate, resistance occurring when the process gas passes through that hole can be further reduced (that is, passage of the process gas can be further facilitated). As a result of this, the respective amounts of the process gas discharged from the plurality of penetrating holes provided in the gas dispersion plate can be certainly made uniform, and thereby uniform substrate processing can be carried out reliably.

Preferably, the perimeter portion has a thickness equal to or more than one half of the thickness of the central portion, and the ones of the plurality of first and second penetrating holes provided in the perimeter portion have a length equal to or more than one half of the length of the ones of the plurality of first and second penetrating holes provided in the central portion.

With this apparatus, the respective amounts of the process gas discharged from the plurality of penetrating holes provided in the gas dispersion plate can be certainly made uniform, and thereby uniform substrate processing can be carried out more reliably.

Preferably, the second substrate processing apparatus further comprises a gas inlet which is connected to the first shower head so that it faces the center of the first gas dispersion plate and which is provided to supply the process gas into the first shower head, and the first gas dispersion plate is detachable.

With this apparatus, by introducing the process gas into the first shower head so that the gas is blown onto the vicinity of the center of the first gas dispersion plate, the respective amounts of the process gas discharged from the plurality of first penetrating holes provided in the first gas dispersion plate can be made uniform certainly, and thereby uniform substrare processing can be carried out reliably. Simultaneously with this, since the first gas dispersion plate is detachable, manufacturing and maintenance of the first shower head and the first gas dispersion plate are facilitated.

Preferably, of the plurality of first and second penetrating holes, the ones provided in the at least either of the gas dispersion plates have circular plan shapes. The penetrating hole of a circular plan shape is easy to form, which easily realizes the effects of the present invention that uniform substrate processing is allowed.

A substrate processing method according to the present invention employs a substrate processing apparatus including: a reaction chamber for processing a substrate using a process gas; a pedestal provided in the reaction chamber and placing the substrate; and a shower head for introducing the process gas into the reaction chamber, the shower head including a gas dispersion plate formed with a plurality of penetrating holes for diffusing the process gas and provided to face the pedestal. This method comprises: the step (a) of placing the substrate onto the pedestal; and the step (b) of supplying the process gas into the reaction chamber through the plurality of penetrating holes formed in the gas dispersion plate, thereby carrying out processing of the substrate. In the step (b), the gas dispersion plate includes a central portion and a perimeter portion having a smaller thickness than the central portion, and the ones of the plurality of penetrating holes provided in the perimeter portion have a smaller length than the ones of the plurality of penetrating holes provided in the central portion, whereby the process gas is supplied uniformly onto the substrate.

With the substrate processing method of the present invention, the penetrating holes provided in the perimeter portion of the gas dispersion plate have a smaller length than the penetrating holes provided in the central portion thereof. From this, resistance occurring when the process gas passes is lower through the penetrating holes provided in the perimeter portion than through the penetrating holes provided in the central portion. Therefore, a decrease in discharge amount is suppressed in the perimeter portion with a lower process gas pressure than the central portion, whereby a uniform discharge amount of the process gas is discharged over the surface of the gas dispersion plate.

Consequently, substrate processing carried out in the step (b) is made uniform over the substrate surface.

Preferably, the plurality of penetrating holes have lengths decreasing with the distance from the center of the gas dispersion plate.

With this method, as the penetrating hole is located more apart from the central portion of the gas dispersion plate, resistance occurring when the process gas passes through that hole can be further reduced. As a result of this, the discharge amount of the process gas can be certainly made uniform over the surface of the gas dispersion plate, and thereby uniform substrate processing can be carried out reliably.

As is apparent from the above, in the substrate processing apparatus of the present invention, the gas dispersion plate is designed so that the perimeter portion has a smaller thickness than the central portion and that the plurality of penetrating holes provided in the perimeter portion of the gas dispersion plate have a smaller length than the penetrating holes in the central portion thereof. With this, the flow rate of the process gas discharged from the plurality of penetrating holes toward the substrate can be made uniform with a higher accuracy than the conventional technique. As a result of this, the uniformity of substrate processing over the substrate surface can be improved more than the conventional technique. This uniformly carries out, for example, dry etching, plasma etching, film formation, and the like, so that the present invention is useful in fabricating a product such as a semiconductor integrated circuit.

### BRIEF DESCRIPTION OF THE DRAWINGS

FIG. 1 is a sectional view showing the inner structre of a substrate processing apparatus (a chemical vapor deposition apparatus 100) according to a first embodiment of the present invention.

FIG. 2A is a plan view showing a gas dispersion plate 107 used for the chemical vapor deposition apparatus 100 according to the first embodiment, and FIG. 2B is a view showing a cross section of the gas dispersion plate 107 taken along the line IIb-IIb′ in FIG. 2A.

FIG. 3 is a graph showing the film thickness distribution (the curve A) in the case where a silicon oxide film is formed on a substrate 103 using the chemical vapor deposition apparatus 100 according to the first embodiment and the film thickness distribution (the curve B) in the case where a silicon oxide film is formed using a conventional chemical vapor deposition apparatus.

FIG. 4 is a sectional view showing the inner structre of a chemical vapor deposition apparatus 200 according to a second embodiment of the present invention.

FIG. 5A is a sectional view showing an example of a conventional chemical vapor deposition apparatus 10, and FIG. 5B is a sectional view showing in enlarged dimension part of a gas dispersion plate 17 provided in the conventional chemical vapor deposition apparatus 10.

### DETAILED DESCRIPTION OF THE PREFERRED EMBODIMENTS

### First Embodiment

Hereinafter, a substrate processing apparatus according to a first embodiment of the present invention will be described with reference to the accompanying drawings.

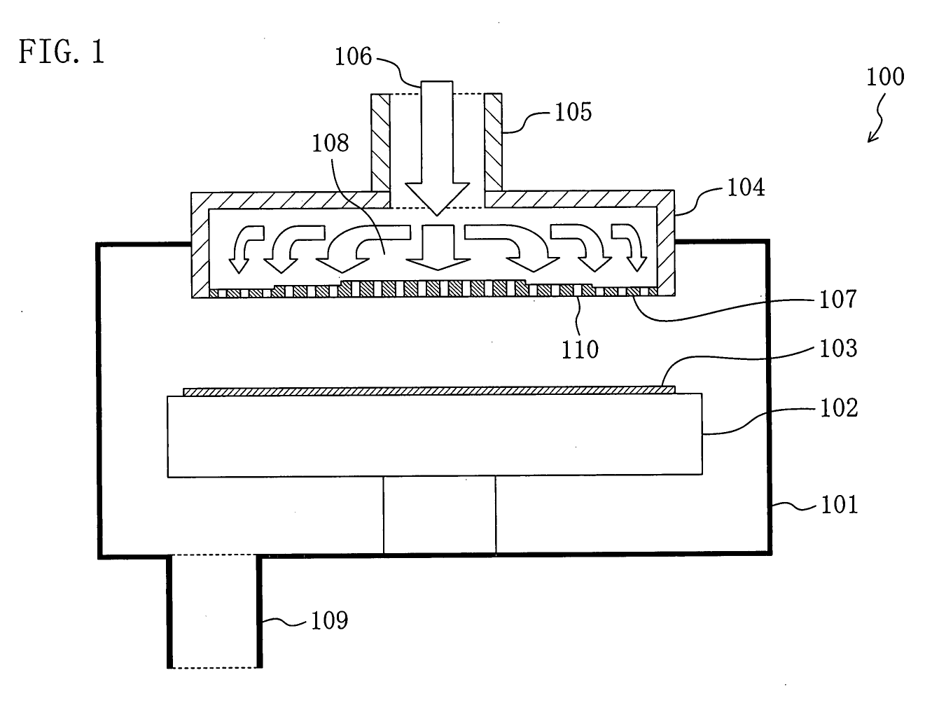

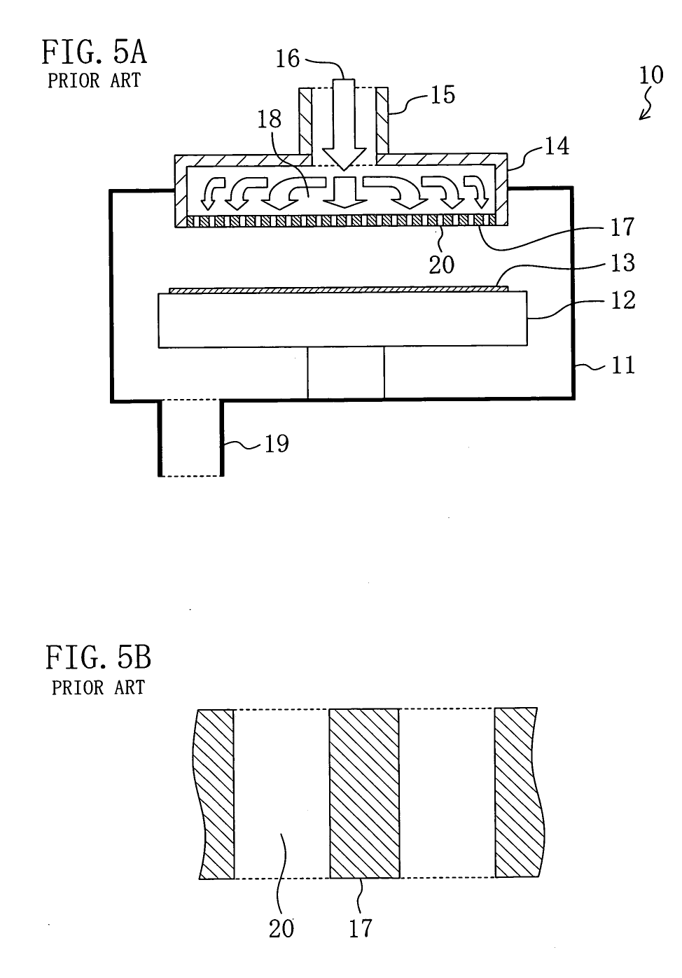

FIG. 1 is a sectional view schematically showing the inner structre of a substrate processing apparatus, more specifically, a chemical vapor deposition apparatus 100 according to the first embodiment of the present invention, which is used to fabricate a semiconductor integrated circuit. The chemical vapor deposition apparatus 100 of the first embodiment and the conventional chemical vapor deposition apparatus 10 shown in FIG. 5A differ in the shape of a gas dispersion plate provided in a shower head. Detailed description of this will be made below.

The chemical vapor deposition apparatus 100 has a pedestal 102 provided in a reaction chamber 101 within which a film is grown, and a substrate 103 to be processed is placed on the pedestal 102. In an upper portion of the reaction chamber 101, a shower head 104 is provided to face the pedestal 102. An upper portion of the shower head 104 is provided with a gas inlet 105, and a source gas 106 is introduced through the gas inlet 105 into the shower head 104.

The side of the shower head 104 facing the substrate 103 (for example, the downside thereof when viewed in the chemical vapor deposition apparatus 100 of FIG. 1) is provided with a gas dispersion plate 107. Thus, the inside of the shower head 104 is formed with a hollow space 108 the gas dispersion plate 107 encloses. As will be described later in detail, the gas dispersion plate 107 is provided with multiple parts having different thicknesses, and the plate has multiple penetrating holes 110 provided in its entire surface. Through the multiple penetrating holes 110, the source gas 106 introduced into the shower head 104 is supplied to the inside of the reaction chamber 101.

Note that the shower head 104 and the gas dispersion plate 107 may be formed integrally. However, it is preferable that they are formed as separable independent components and used in combination because such a structure makes it easy to do manufacturing and maintenance of the shower head 104 and the gas dispersion plate 107.

The reaction chamber 101 is provided with an exhaust vent 109, and the apparatus is designed so that a pump (not shown) can exhaust gas from the inside of the reaction chamber 101. The pedestal 102 is provided with a heater (not shown) for adjusting the temperature of the substrate 103.

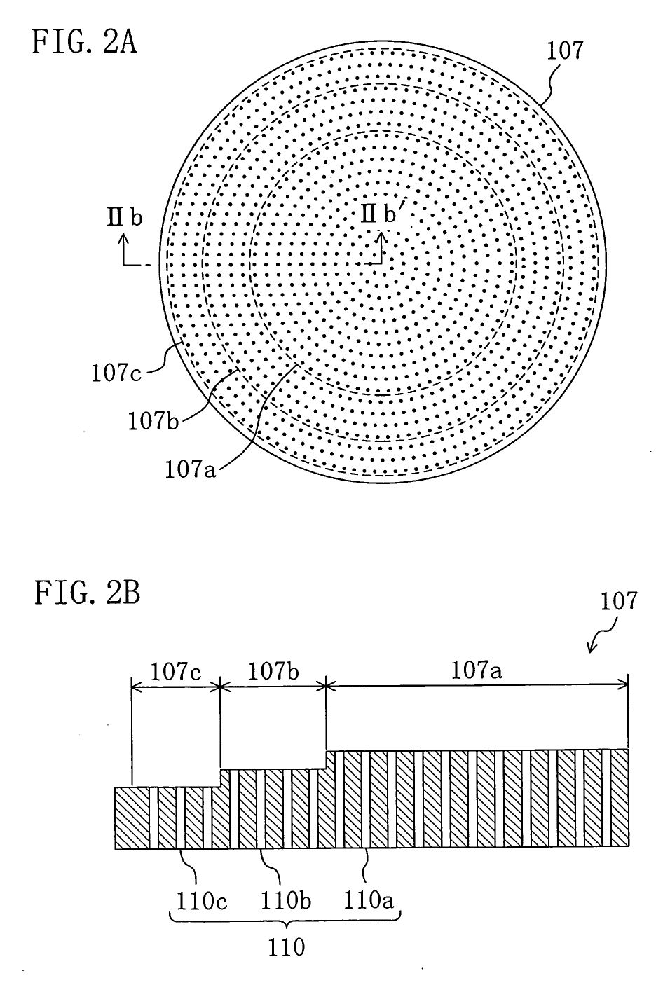

Next detailed description will be made of the gas dispersion plate 107. FIG. 2A is a view showing the plan structure of the gas dispersion plate 107 used in the first embodiment, and FIG. 2B is a view schematically showing a cross section taken along the line IIb-IIb′ in FIG. 2A.

Referring to FIG. 2A, the planar shape of the gas dispersion plate 107 is circular. This shape is designed to fit the circular plan shape of the substrate 103, so that it is a preferable shape. However, the planar shape thereof is not limited to this. Through the gas dispersion plate 107, for example, thousands of circular penetrating holes 110 are bored so that the holes are arranged concentrically at a uniform density over the entire surface thereof.

As shown in FIGS. 2A and 2B, the gas dispersion plate 107 has three regions in concentric arrangement, and respective regions differ in thickness. To be more specific, the three regions are: a circular central portion 107a which is located at the centermost point of the gas dispersion plate 107 and which is the thickest of the three regions; an annular intermediate portion 107b which is located outside the central portion 107a and which is thinner than the central portion 107a; and an annular perimeter portion 107c which is located outside the intermediate portion 107b (in other words, at the most outside of the gas dispersion plate 107) and which is thinner than the intermediate portion 107b (in other words, the thinnest portion).

By such a structure, the respective penetrating holes 110 in the three regions shown above differ in length, and the hole located more outside has a smaller length. To be more specific, the thickest central portion 107a includes the longest penetrating holes 110a, the second thickest intermediate portion 107b includes the second longest penetrating holes 110b, and the thinnest perimeter portion 107c includes the shortest penetrating holes 110c.

Note that the gas inlet 105 is disposed to blow the source gas 106 onto the vicinity of the center of the gas dispersion plate 107.

The following can be gevien as a concrete example of a preferable dimension of the gas dispersion plate 107. Note that in this example, description will be made of a preferable dimention in the case where the substrate 103 has a diameter of 200 mm.

First, the gas dispersion plate 107 preferably has a diameter from 180 mm to 220 mm inclusive, and more preferably, a diameter of, for example, 200 mm.

The area of the gas dispersion plate 107 ranging from the center to a radius of 60 mm is the central portion 107a with a thickness of 6.5 mm, and the lengths of the penetrating holes 110a provided therein are also 6.5 mm. Further, the area thereof located outside the central portion 107a and ranging, in radius from the center, from 60 to less than 80 mm is the intermediate portion 107b with a thickness of 5.5 mm, and the lengths of the penetrating holes 110b provided therein are also 5.5 mm. Moreover, the area thereof located outside the intermediate portion 107b (in other words, the outermost area of the gas dispersion plate 107) and ranging, in radius from the center, from 80 to 100 mm inclusive is the perimeter portion 107c with a thickness of 4.5 mm, and the lengths of the penetrating holes 110c provided therein are also 4.5 mm.

Next description will be made of a method for processing the substrate 103 using the chemical vapor deposition apparatus 100 above mentioned, more specifically, a method for forming a film on the substrate 103.

First, the substrate 103 is placed on the pedestal 102 provided within the reaction chamber 101 of the chemical vapor deposition apparatus 100. The pedestal 102 supports the substrate 103 to face the gas dispersion plate 107 of the shower head 104.

Subsequently, using a pump (not shown), gas is exhausted through the exhaust vent 109 to reduce the pressure within the reaction chamber 101. In addition, using a heater (not shown) installed in the pedestal 102, the substrate 103 is heated to a predetermined temperature.

Then, the source gas 106 is introduced from the gas inlet 105 into the shower head 104. The source gas 106 is introduced so that it is blown toward the vicinity of the center of the gas dispersion plate 107 within the hollow space 108 of the shower head 104. The introduced source gas 106 is diffused within the hollow space 108 toward the perimeter of the gas dispersion plate 107. Simultaneously with this, through the penetrating holes 110 (110a, 110b, and 110c) provided in the gas dispersion plate 107, the source gas 106 is supplied onto the substrate 103 placed in the reaction chamber 101. In the manner described above, a film is formed on the substrate 103.

In the case as a concrete example where a BPSG (boro-phospho silicate-glass) film is formed, the substrate 103 may be heated to 400° C., and use as the source gas 106 may be made of a mixed gas of a TEOS (Tetraethyl Orthosilicate) gas, an ozone gas, a TEPO (Triethyl phosphate) gas, and a TEB (Triethyl borate) gas. This allows a film formation on the substrate 103 by heat of reaction from the mixed gas.

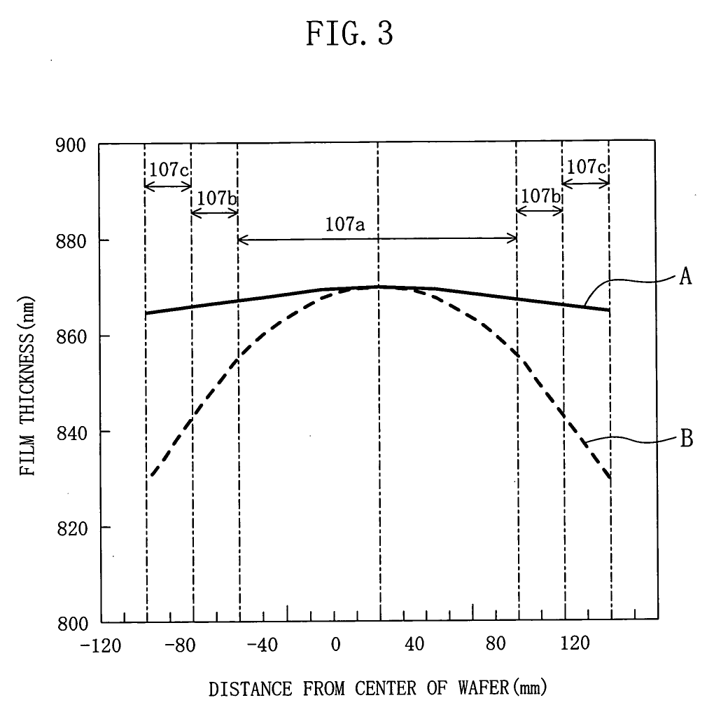

FIG. 3 shows, as a graph, the film thickness distribution A in the case where a film is formed in the manner described above using the chemical vapor deposition apparatus 100 of the first embodiment and the film thickness distribution B in the case where a film is formed using the conventional chemical vapor deposition apparatus. In FIG. 3, the thickness of the formed film is plotted in ordinate, and the distance from the center of the substrate 103 is plotted in abscissa. The distance as abscissa is shown so that the positive direction is the direction from the center toward one side on the line and the negative direction is the direction toward the other side. The regions represented by 107a, 107b, and 107c in FIG. 3 correspond to the central portion 107a, the intermediate portion 107b, and the perimeter portion 107c of the gas dispersion plate 107, respectively.

As is apparent from FIG. 3, the film thickness A in the first embodiment has a more improved uniformity than the film thickness distribution B in the conventional technique. In this description, the uniformity of the film thickness indicates the value of thickness of a film formed over a single substrate surface, which is obtained by dividing the difference between the maximum and the minimum by the double of the average. Regarding the film thickness uniformity by this definition, the film thickness distribution B in the conventional technique has a uniformity beyond 3%, while the distribution A in the first embodiment has a uniformity of 1.2%.

In the case of the gas dispersion plate 17 of the conventional chemical vapor deposition apparatus 10 shown in FIG. 5A, the discharge amount of the source gas is nonuniform over the surface of the gas dispersion plate 17, as an instance, the discharge amount of the source gas 16 from the penetrating holes 20 provided around the center is larger than that from the penetrating holes 20 provided around the perimeter. This causes a decrease in the thickness uniformity of the formed film.

On the other hand, in the case of the gas dispersion plate 107 provided in the chemical vapor deposition apparatus 100 of the first embodiment, the discharge amount of the source gas 106 from the penetrating holes 110 within the surface of the gas dispersion plate 107 becomes more uniform than that of the conventional technique. This is accomplished by the following approach; the gas dispersion plate 107 includes the central portion 107a, the intermediate portion 107b, and the perimeter portion 107c of which respective thicknesses decrease in this order from the center toward the perimeter, so that the lengths of the penetrating holes 110a, 110b, and 110c provided in the associated films decrease in this order toward the perimeter.

As a further description, first, within the hollow space 108, the pressure of the source gas 106 falls outward from the center (from the vicinity of the central portion 107a toward the perimeter portion 107c). This results in nonuniformity of the discharge amount of the source gas 16 in the conventional chemical vapor deposition apparatus 10. In contrast to this, since in the gas dispersion plate 107 the lengths of the penetrating holes 110 decrease outward from the inner side, resistance given to the source gas 106 in passing through the penetrating holes 110 is reduced. Therefore, as the holes are located outward, the gas is more likely to be discharged even by a lower pressure. As a result of this, the discharge amount of the source gas 106 over the surface of the gas dispersion plate 107 becomes less dependent on the position on the plate, resulting in a more uniform discharge.

As is apparent from the above, film formation on the substrate 103 using the chemical vapor deposition apparatus 100 of the first embodiment improves the uniformity of the film thickness as compared with the conventional technique.

Improvement in film thickness uniformity by controlling the diameters of the penetrating holes, as the conventional technique, was hard to realize because it is extremely difficult to carry out hole formation with a demanded accuracy (control of diameters of the penetrating holes).

In contrast to this, in the first embodiment, the gas dispersion plate 107 has the structure composed of multiple parts with different thicknesses, and thereby multiple penetrating holes 110 with diffirent lengths are provided therein. This approach requires only a relatively low accuracy of hole formation demanded, which is easily realizable.

In the first embodiment, in the case of forming an interlayer insulating film particularly made of a silicon oxide film or an organic silicate film, a tungsten metal film for a tungsten plug filling a contact hole, or the like, the film having a thickness uniformity of 3% or lower is deposited, and then the surface of the deposited film is planarized by a chemical mechanical polishing (CMP). Thereby, a planarization process with a very excellent controllability can be carried out.

In the first embodiment, the thicknesses of the three parts of the gas dispersion plate 107 and the lengths of the penetrating holes 110 are determined to satisfy the uniformity demanded of each farication process for film formation.

For example, the gas dispersion plate 107 of the first embodiment includes the three parts with different thicknesses (the central portion 107a, the intermediate portion 107b, and the perimeter portion 107c), and thus it has the penetrating holes 110 with three different lengths (the penetrating holes 110a, 110b, and 110c). However, this plate is not limited to this structure. For example, as long as the gas dispersion plate is provided with penetrating holes having at least two different lengths and the penetrating holes in the perimeter portion are shorter, the effects of the present invention can be exerted. Alternatively, the penetrating holes with four or more different lengths may be provided therein.

An example of a concrete dimension of the gas dispersion plate 107 has been shown previously. However, the dimention thereof is not limited to these values, and it is sufficient to set this dimension in agreement with the diameter of the substrate 103, the type and condition of processing to be conducted, or the like.

In particular, it is sufficient that there is a difference in length beyond 0 mm between the penetrating hole 110a of the central portion 107a and the penetrating hole 110c of the perimeter portion 107c. More preferably, it is sufficient that there is a difference in length beyond 0.5 mm therebetween. In other words, if the penetrating hole 110c is shorter than the penetrating hole 110a, the effect of making the discharge amount of the source gas 106 uniform over the surface of the gas dispersion plate 107 is achieved. In particular, the case of a difference of 0.5 mm or larger certainly achieves this effect.

Preferably, the length of the penetrating hole 110c of the perimeter portion 107c is equal to or more than one half of the length of the penetrating hole 110a of the central portion 107a. To realize this, it is sufficient that the thickness of the perimeter portion 107c is equal to or more than one half of the thickness of the central portion 107a.

The thickness of the gas dispersion plate 107 of the first embodiment decreases stepwise from the inner side toward the outer side. Instead of this, the thickness of the plate may decrease smoothly from the inner side toward the outer side. Also by such an approach, the length of the penetrating hole can decrease sequentially from the inner side toward the outer side.

### Second Embodiment

Next, a substrate processing apparatus according to a second embodiment of the present invention will be described with reference to the accompanying drawings.

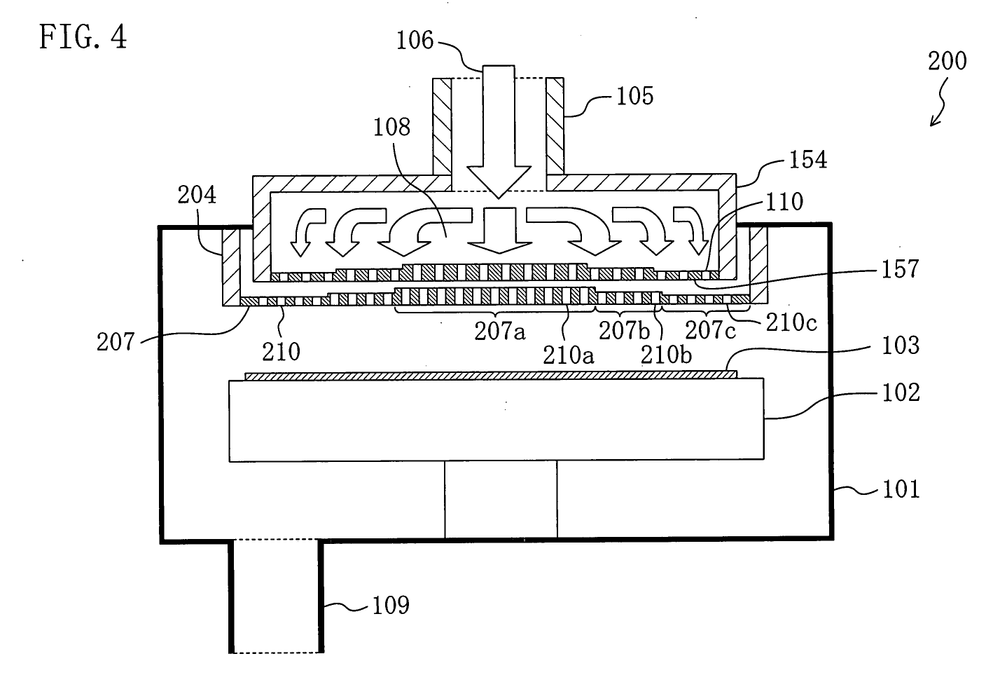

FIG. 4 is a sectional view schematically showing the inner structre of a substrate processing apparatus, more specifically, a chemical vapor deposition apparatus 200 according to the second embodiment of the present invention, which is used to fabricate a semiconductor integrated circuit.

The chemical vapor deposition apparatus 200 has the structure in which a second shower head 204 and a second gas dispersion plate 207 are added to the chemical vapor deposition apparatus 100 of the first embodiment. Thus, the description of the components of the chemical vapor deposition apparatus 200 shown in FIG. 4 that are the same as those of the chemical vapor deposition apparatus 100 of the first embodiment will be omitted by retaining the same reference numerals as FIG. 1.

Referring to FIG. 4, the chemical vapor deposition apparatus 200 of the second embodiment is provided with a first shower head 154 and a first gas dispersion plate 157 having the same structures as the shower head 104 and the gas dispersion plate 107 in the chemical vapor deposition apparatus 100 of the first embodiment. Specifically, the source gas 106 introduced from the gas inlet 105 is diffused in the hollow space 108 formed of the first shower head 154 and the first gas dispersion plate 157, and then discharged through the penetrating holes 110 provided in the first gas dispersion plate 157. In the second embodiment, similarly to the gas dispersion plate 107 in the first embodiment shown in FIGS. 2A and 2B, the first gas dispersion plate 157 includes three parts with thicknesses concentrically decreasing outward. Thereby, three types of penetrating holes 110 with different lengths are present in this plate, and the hole located more outside has a smaller length.

Further, the second shower head 204 including the second gas dispersion plate 207 is provided to surround the first shower head 154. By this structure, the source gas 106 dischraged through the first gas dispersion plate 157 is blown onto the second gas dispersion plate 207. Then, the blown gas passes through multiple penetrating holes 210 provided in the second gas dispersion plate 207, and is supplied into the reaction chamber 101. In the manner shown above, the source gas 106 is supplied onto the substrate 103 placed within the reaction chamber 101.

In the second embodiment, the second gas dispersion plate 207 has the same structure as the gas dispersion plate 107 shown in FIGS. 2A and 2B. Specifically, it has: a central portion 207a which is the thickest of the three regions; an intermediate portion 207b which is located outside the central portion 207a and which is the second thickest of the three regions; and a perimeter portion 207c which is located outside the intermediate portion 207b (at the most outside of the second gas dispersion plate 207) and which is the thinnest of the three regions. By the structure of the the second gas dispersion plate 207, a plurality of penetrating holes 210 concentrically provided in the respective regions include: penetrating holes 210a with the largest length, penetrating holes 201b with the second largest length, and penetrating holes 201c with the smallest length, which are provided in this order from the center.

The second gas dispersion plate 207 has such a structure. Therefore, like the gas dispersion plate 107 of the first embodiment, when the pressure of gas at the outer side (the vicinity of the perimeter portion 207c) is lower than that at the inner side (the vicinity of the central portion 207a), the source gas 106 can be discharged uniformly over the surface of the second gas dispersion plate 207.

As described above, in the chemical vapor deposition apparatus 200 according to the second embodiment, the source gas 106 discharged from the first gas dispersion plate 157 is supplied through the second gas dispersion plate 207 onto the substrate 103. Thus, the amount of the source gas 106 supplied onto the substrate 103 can be made more uniform over the surface of the substrate 103. As a result of this, processing exhibiting a higher uniformity than the conventional technique can be carried out reliably on the substrate 103. For example, a film can be reliably formed which has a higher thickness uniformity over the surface of the substrate 103 than the conventional technique.

Note that the chemical vapor deposition apparatus 200 employs the first gas dispersion plate 157 and the second gas dispersion plate 207 both of which have the structure shown in FIGS. 2A and 2B. Alternatively, only one of the first gas dispersion plate 157 and the second gas dispersion plate 207 may have the structure shown in FIGS. 2A and 2B. In this case, as the other gas dispersion plate, use is made of the conventional gas dispersion plate in which the penetrating holes with an equal length are formed over the entire surface thereof. Such a construction can also provide a more uniform amount of the source gas 106 supplied onto the substrate 103 than the conventional technique.

That is to say, if the first gas dispersion plate 157 has the structure of the present invention shown in FIG. 2A or the like, the source gas 106 to be introduced through the first shower head 154 into the second shower head 204 has a uniform discharge amount at the time of passing through the surface of the first gas dispersion plate 157. Thereby, the second shower head 204 can supply the source gas 106 uniformly onto the substrate 103.

On the other hand, if the second gas dispersion plate 207 has the structure shown in FIG. 2A or the like, the source gas 106 is supplied nonuniformly by the first gas dispersion plate 157 with the conventional structure. That is to say, in the first gas dispersion plate 157, the discharge amount of the source gas 106 from the penetrating holes 110 around the perimeter is smaller than that around the center. However, by passing through the second gas dispersion plate 207, the source gas 106 can be supplied uniformly onto the substrate 103.

Further, if both of the first gas dispersion plate 157 and the second gas dispersion plate 207 have the structure of the present invention, the supply amout of the source gas 106 onto the substrate 103 can be made uniform more reliably.

For the first gas dispersion plate 157 and the second gas dispersion plate 207, determination of which of the conventional structure and the structure of the present invention is employed, determination of thickness of the gas dispersion plate, determination of length of the penetrating hole, and the like may be made to suit the processing condition.

In the first and second embodiments, all the penetrating holes have circular plan shapes. However, the reason why they are circular is that a drill bores those holes through the gas dispersion plate, so that they may have another shape.

The chemical vapor deposition apparatus of the present invention exerts an outstanding effect particularly in processing a substrate of a large diameter (for example, a diameter of 200 to 300 mm or the like). The reason for this is that since enlargement of diameter of a substrate increases the diameters of the shower head and the gas dispersion plate, the pressure difference of the source gas is likely to widen between the vicinity of the center and the vicinity of the perimeter of the gas dispersion plate. That is to say, also in such a case, influences of the pressure difference can be relieved and the discharge amount of the source gas over the surface of the gas dispersion plate can be made uniform.

In the first and second embodiments, description has been mainly made of the case of a thermal vapor phase epitaxy, but an applicable process is not limited to this. If, similarly to the cases shown in FIGS. 1 and 4, the substrate processing apparatus has the structure in which a process gas is supplied onto a substrate through a plurality of penetrating holes provided in the gas dispersion plate, the effect of making a difference in length among the penetrating holes can be realized. For example, in a plasma CVD apparatus, a dry etching apparatus, a various types of ashing apparatus, other plasma or gas surface treatment apparatus, and the like, the gas dispersion plate according to the present invention can be used to improve the uniformity of processing on the substrate.

This approach can improve not only the film thickness uniformity in film formation described as the first and second embodiments but also the uniformity of, for example, the etching rate, the etching amount, the ashing amount, and the growth amount of film coating. For example, the uniformity over the substrate surface can be 3% or lower.

What is claimed is:

1. A substrate processing apparatus comprising:
a reaction chamber for processing a substrate using a process gas;
a pedestal for placing the substrate, the member being provided in the reaction chamber; and
a shower head for introducing the process gas into the reaction chamber,
wherein the shower head includes a gas dispersion plate which is formed with a plurality of penetrating holes for diffusing the process gas and is provided to face the pedestal,
the gas dispersion plate includes a central portion and a perimeter portion having a smaller thickness than the central portion, and
the ones of the plurality of penetrating holes provided in the perimeter portion have a smaller length than the ones of the plurality of penetrating holes provided in the central portion.

2. The apparartus of claim 1,
wherein the gas dispersion plate has a thickness decreasing with the distance from the center of the gas dispersion plate, and
the plurality of penetrating holes have lengths decreasing with the distance from the center of the gas dispersion plate.

3. The apparartus of claim 1,
wherein the perimeter portion has a thickness equal to or more than one half of the thickness of the central portion, and
the ones of the plurality of penetrating holes provided in the perimeter portion have a length equal to or more than one half of the length of the ones of the plurality of penetrating holes provided in the central portion.

4. The apparartus of claim 1, further comprising a gas inlet which is connected to the shower head so that it faces the central portion of the gas dispersion plate and which is provided to introduce the process gas into the shower head,
wherein the gas dispersion plate is detachable.

5. The apparartus of claim 1,
wherein the plurality of penetrating holes have circular plan shapes.

6. A substrate processing apparatus comprising:
a reaction chamber for processing a substrate using a process gas;
a pedestal for placing the substrate, the member being provided in the reaction chamber;
a first shower head for introducing the process gas into the reaction chamber; and
a second shower head formed to surround the first shower head and discharging the process gas into the reaction chamber,
wherein the first shower head includes a first gas dispersion plate which is formed with a plurality of first penetrating holes for diffusing the process gas,
the second shower head includes a second gas dispersion plate which is formed with a plurality of second penetrating holes for diffusing the process gas and is provided to face the pedestal,
at least either of the first and second gas dispersion plates includes a central portion and a perimeter portion having a smaller thickness than the central portion, and
the ones of the plurality of first and second penetrating holes provided in the perimeter portion have a smaller length than the ones of the plurality of first and second penetrating holes provided in the central portion.

7. The apparartus of claim 6,
wherein the at least either of the gas dispersion plates indicates both of the first and second gas dispersion plates.

8. The apparartus of claim 6,
wherein the at least either of the gas dispersion plates has a thickness decreasing with the distance from the center of the at least either of the gas dispersion plates, and
of the plurality of first and second penetrating holes, the ones formed in the at least either of the gas dispersion plates have lengths decreasing with the distance from the center of the at least either of the gas dispersion plates.

9. The apparartus of claim 6,
wherein the perimeter portion has a thickness equal to or more than one half of the thickness of the central portion, and
the ones of the plurality of first and second penetrating holes provided in the perimeter portion have a length equal to or more than one half of the length of the ones of the plurality of first and second penetrating holes provided in the central portion.

10. The apparatus of claim 6, further comprising a gas inlet which is connected to the first shower head so that it faces the center of the first gas dispersion plate and which is provided to supply the process gas into the first shower head,
wherein the first gas dispersion plate is detachable.

11. The apparartus of claim 6,
wherein of the plurality of first and second penetrating holes, the ones provided in the at least either of the gas dispersion plates have circular plan shapes.

12. A substrate processing method which employs a substrate processing apparatus including: a reaction chamber for processing a substrate using a process gas; a pedestal provided in the reaction chamber and placing the substrate; and a shower head for introducing the process gas into the reaction chamber, the shower head including a gas dispersion plate formed with a plurality of penetrating holes for diffusing the process gas and provided to face the pedestal, the method comprising:
the step (a) of placing the substrate onto the pedestal; and
the step (b) of supplying the process gas into the reaction chamber through the plurality of penetrating holes formed in the gas dispersion plate, thereby carrying out processing of the substrate,
wherein in the step (b), the gas dispersion plate includes a central portion and a perimeter portion having a smaller thickness than the central portion, and the ones of the plurality of penetrating holes provided in the perimeter portion have a smaller length than the ones of the plurality of penetrating holes provided in the central portion, whereby the process gas is supplied uniformly onto the substrate.

13. The method of claim 12,
wherein the plurality of penetrating holes have lengths decreasing with the distance from the center of the gas dispersion plate.
